(19) United States
(12) Patent Application Publication
(10) Pub. No.: US 2025/0084557 A1
(43) Pub. Date: Mar. 13, 2025

(54) GROWTH OF STRONTIUM TETRABORATE CRYSTALS

(71) Applicant: KLA CORPORATION, Milpitas, CA (US)

(72) Inventors: Yung-Ho Alex CHUANG, Cupertino, CA (US); John FIELDEN, Los Altos, CA (US); Kelly MAUSER, Santa Clara, CA (US); Edgardo GARCIA BERRIOS, San Jose, CA (US)

(21) Appl. No.: 18/752,650

(22) Filed: Jun. 24, 2024

Related U.S. Application Data
(60) Provisional application No. 63/656,193, filed on Jun. 5, 2024.
(60) Provisional application No. 63/537,558, filed on Sep. 11, 2023.

(51) Int. Cl. C30B 9/12; C30B 29/22; G02F 1/35; G02F 1/355

(52) U.S. Cl. CPC C30B 9/12; C30B 29/22; G02F 1/3548; G02F 1/3551

(57) ABSTRACT

A method for growing a strontium tetraborate (SrB4O7) crystal is provided. The method includes lowering a seed crystal into a melt having a mixture comprising a source of Sr, B, O, and Cl. The method also includes heating and melting the mixture to a temperature sufficient to form a strontium tetraborate crystal.

### CROSS-REFERENCE TO RELATED APPLICATIONS

This application is related to U.S. Provisional Patent Application No. 63/656,193, filed Jun. 5, 2024, and U.S. Provisional Patent Application No. 63/537,558, filed Sep. 11, 2023, the disclosures of which are each incorporated by reference herein in their entireties.

### FIELD OF THE DISCLOSURE

The disclosure relates to crystal growth and, more particularly, to growth of a single-crystal material, strontium tetraborate (SrB₄O₇), for linear or nonlinear optical components such as mirrors, lenses, prisms, beam splitters, windows, lamp cells, quasi-phase matched and other frequency conversion designs for use in metrology and inspection systems in semiconductor manufacturing, including those used to inspect and/or measure photomasks, reticles, and semiconductor wafers.

### BACKGROUND

As semiconductor devices' dimensions shrink, the size of the smallest particle or pattern defect that can cause a device to fail also shrinks. Hence, a need arises for detecting smaller particles and defects on patterned and unpatterned semiconductor wafers and reticles. The intensity of light scattered by particles smaller than the wavelength of that light generally scales as a high power of the dimensions of that particle (for example, the total scattered intensity of light from an isolated, small, spherical particle scales proportional to the sixth power of the diameter of the sphere and inversely proportional to the fourth power of the wavelength). Because of the increased intensity of the scattered light, shorter wavelengths will generally provide better sensitivity for detecting small particles and defects than longer wavelengths. Therefore, high speed inspection in the semiconductor industry in commonly performed in machines utilizing ultraviolet light. One method to generate ultraviolet (UV) light involves using nonlinear crystals transparent in the UV to frequency convert from longer wavelengths to UV wavelengths.

Since the intensity of light scattered from small particles and defects is generally very low, high illumination intensity is required to produce a signal that can be detected in a very short time. This necessitates using windows, lenses, and other optics with high damage threshold, in addition to the requirement of high UV transmission.

Linear and nonlinear optical crystals are used in microscopes, telescopes, virtual reality systems, lasers, and semiconductor systems, as an example. Optical crystals are used extensively in semiconductor inspection and metrology systems, including in prisms, lenses, laser crystals, and windows among other parts.

Few optical crystals exist that are transparent in the deep ultraviolet (DUV) and vacuum ultraviolet (VUV) from approximately 200-280 nm and 100-200 nm, respectively. The most commonly used optical crystals for linear optics applications are calcium fluoride and magnesium fluoride, which transmit light with wavelengths as short as approximately 130 nm. However, most fluorides are hygroscopic, or absorb water from the atmosphere. This water will absorb UV light, and the absorbed water can cause stresses in the crystals which can lead to altered shape of the optics, reducing performance.

Nonlinear optical crystals capable of frequency conversion for wavelengths shorter than approximately 190 nm are not commercially available. Several materials, such as Potassium beryllium fluoroborate KBe₂BO₃F₂ (KBBF) and others in the ABe₂BO₃F₂ (A=Na, K, Rb, Cs, TI, NH₄) can transmit wavelengths shorter than 190 nm and can be phase-matched. However, KBBF transmission drops significantly for wavelengths shorter than 190 nm. Additionally, growth of these materials in large quantities has not yet been achieved, and more research is needed on their damage thresholds and lifetimes.

Strontium tetraborate, SrB₄O₇ (SBO) is a material which overcomes many of the above obstacles. SBO is transmissive for wavelengths as short as approximately 125 nm (see Y. S. Oseledchik, A. L. Prosvirnin, A. I. Pisarevskiy, V. V. Starshenko, V. V. Osadchuk, S. P. Belokrys, N. V. Svitanko, A. S. Korol, S. A. Krikunov, and A. F. Selevich, “New nonlinear optical crystals: strontium and lead tetraborates,” Opt. Mater. 4, 669 (1995), which is incorporated by reference herein in the entirety), is not hygroscopic, has a damage threshold at 266 nm of 16.4 J/cm² which is higher than that of CaF₂ (Tanaka et al., “High surface laser-induced damage threshold of SBO single crystals under 266-nm (DUV) laser irradiation” Optics Express, 28, 20 29239 (2020)) and other nonlinear crystals such as CLBO. While SBO cannot be phase-matched in the DUV or VUV due to its small birefringence, it has a large d₃₃ nonlinear coefficient and can thus be quasi-phase matched. See U.S. Provisional Patent Application No. 63/038,134, entitled “177 nm and 133 nm CW Lasers Using Stacked Strontium Tetraborate Plates”, which was filed on Jun. 12, 2020, to U.S. Provisional Patent Application No. 63/076,391, entitled “152 nm and 177 nm CW Lasers Using Stacked Strontium Tetraborate Plates”, which was filed on Sep. 10, 2020, to U.S. Pat. No. 11,237,455, entitled “Frequency Conversion Using Stacked Strontium Tetraborate Plates”, to U.S. Provisional Patent Application No. 63/282,706, entitled “Frequency Conversion Using Interdigitated Nonlinear Crystal Gratings”, which was filed on Nov. 24, 2021, and to U.S. Patent Application (KLA P6074), entitled “193 nm Laser Using Strontium Tetraborate For Frequency Conversion”, incorporated by reference herein in their entirety.

SBO growth has been demonstrated using the Czochralski method, micro-pulling method, hydrothermal method, and top-seeded solution growth. The Czochralski growth method produces a crystal with anti-parallel domains of random thickness along the z crystal axis. This is possibly due to incompletely formed boron ion networks during growth caused by microscopic growth parameter variations which seed inverted domains (Aleksandrovsky, A. S., Vyunishev, A. M., and Zaitsev, A. I., “Applications of Random Nonlinear Photonic Crystals Based on Strontium Tetraborate”, Crystals, 2, 1393-1409 (2012)). The micro-pulling method does not produce crystals large enough for most optics applications. The hydrothermal method has shown promise for growth of SBO, but large crystals have not yet been demonstrated and more work needs to be done to develop this technique. The top-seeded solution method has demonstrated the largest, purest SBO single-crystal to date, with a mass of 300 g as shown by Y. Tanaka, et al. in “Kyropoulos growth of a 300 g SrB₄O₇ single crystal using a twin-type stirring blade,” Japanese Journal of Applied Physics, 61, 07503 (2022), included herein by reference in its entirety. The melt used by Y. Tanaka et al. was a B-rich self-flux composed of 67.3% B₂O₃ and 32.7% SrCO₃. Such a large B₂O₃ concentration in the melt causes high viscosity, around 1 Pa·s. High viscosity due to high B₂O₃ concentration has been observed during the growth of other borate crystals, such as LBO with 87.5 wt % B₂O₃ and viscosity of 6.3 Pa·s (Parfeniuk C., “Growth of lithium triborate crystals II. Experimental results”, J. Crystal Growth 158 (1996)). The high viscosity of the melt reduces fluid velocity and mixing during crystal growth, resulting in a higher defect density and therefore more absorption and scattering of light. The high viscosity also necessitates a slow crystal growth rate in order to ensure sufficient mixing is taking place in the melt. To cut, polish, and etch SBO for use in linear and nonlinear optical components, SBO boules of several centimeters in dimension must be grown in sufficient quantity, which requires a higher growth rate with a lower defect density.

Solution growth, or growing a crystal from a non-stoichiometric melt containing a solvent or flux, is one method of growing larger crystals with lower defect densities or at lower temperatures. Finding a compatible flux from the nearly innumerable options available can be difficult; the flux must have an appropriate melting and boiling point, viscosity, and must not be incorporated into the target crystal during growth. For example, an array of different fluxes were used to grow β-BBO of varying quality before a flux of Na₂O was discovered to produce high quality crystals. While Tanaka et al. used a slight borate self-flux to grow SBO from a highly-viscous melt, flux growth of SBO using other compounds has not been attempted or explored to our knowledge. One flux compound, SrCl₂ has been used as a flux in crystal growths, including lead tungstate (PbWO₄) in a non-seeded solution growth shown by Arora, S. K., and Chudasam, B., in “Flux Growth and Optoelectronic Study of PbWO₄ Single Crystals”, Crystal Growth and Design, 7, 2, (2007). SrCl₂ has also been used as a flux in the high temperature solid state reaction method growth of SrAl₂O₄:Eu²⁺, Dy³⁺ by Li, B., et al in “Effects of SrCl₂ as a flux on the structural and luminescent properties of SrAl₂O₄:Eu²⁺, Dy³⁺ phosphors for AC-LEDs”, in J. Alloys and Compounds, 651 (2015). The growth methods, crystal structures, crystal qualities, crystal sizes, and applications of these two materials are distinct from those of the high quality SBO needed for VUV optics and frequency conversion.

An SBO growth method to overcome the above-mentioned limitations would be well received in relevant industries.

### SUMMARY OF THE DISCLOSURE

The present disclosure generally relates to a method of growing SBO with a melt or solution method comprising strontium chloride (SrCl₂) as a flux and component of the melt or solution, in accordance with one or more embodiments of the present disclosure. These SBO crystals are grown with the Kyropoulos method, high temperature solution top-seeding method, seeded hydrothermal method, or other seeded or non-seeded flux, solution, or melt method.

An optical system is disclosed, in accordance with one or more embodiments of the present disclosure. In one illustrative embodiment, the optical system includes one or more of a linear and a nonlinear optical component, wherein at least a portion of the one or more of a linear and a nonlinear optical component is formed from strontium tetraborate.

An optical system is disclosed, in accordance with one or more additional and/or alternative embodiments of the present disclosure. In one illustrative embodiment, the optical system includes a stage for supporting a sample. In another illustrative embodiment, the optical system includes an illumination source. In another illustrative embodiment, the optical system includes one or more linear optical components configured to direct illumination from the illumination source to the sample, wherein at least a portion of the one or more linear and nonlinear optical components are formed from strontium tetraborate.

A method for crystal growth is disclosed, in accordance with one or more embodiments of the present disclosure. In one illustrative embodiment, the crystal growth method includes a furnace for growing the crystal. In another illustrative embodiment, the crystal growth method includes a solution comprising a source of strontium, oxygen, boron, and strontium chloride for growth of strontium tetraborate.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF THE DRAWINGS

The numerous advantages of the disclosure may be better understood by those skilled in the art by reference to the accompanying figures in which:

FIG. 1 is a simplified block diagram showing an exemplary inspection or metrology system according to one aspect of the disclosure;

FIG. 2 illustrates an ultraviolet lamp incorporating SrBO as an optical glass material for one or more optical components, in accordance with one or more embodiments of the disclosure; and

FIG. 3 is a simplified diagram showing an exemplary furnace for growing SBO according to one aspect of the disclosure.

### DETAILED DESCRIPTION

The present disclosure relates to an improvement in growth quality and growth rate for SBO crystals for semiconductor inspection systems. The following description is presented to enable one of ordinary skill in the art to make and use the invention as provided in the context of a particular application and its requirements. As used herein, directional terms such as “top”, “left”, “right”, “horizontal” and “downward” are intended to provide relative positions for purposes of description and are not intended to designate an absolute frame of reference. Various modifications to the described embodiments will be apparent to those with skill in the art, and the general principles defined herein may be applied to other embodiments. Therefore, the present disclosure is not intended to be limited to the particular embodiments shown and described but is to be accorded the widest scope consistent with the principles and novel features herein disclosed.

Various aspects of the disclosure relate to the following references, which are each incorporated by reference herein in their entireties: U.S. Provisional Patent Application No. 63/521,880, entitled “Growth of Quasi-Phase Matched Strontium Tetraborate and Lithium Triborate Crystals for Frequency Conversion”, which was filed on Jun. 20, 2023; to U.S. Provisional Patent Application No. 63/038,134, entitled “177 nm and 133 nm CW Lasers Using Stacked Strontium Tetraborate Plates”, which was filed on Jun. 12, 2020; to U.S. Provisional Patent Application No. 63/076,391, entitled “152 nm and 177 nm CW Lasers Using Stacked Strontium Tetraborate Plates”, which was filed on Sep. 10, 2020; to U.S. patent application Ser. No. 17/991,198, entitled “193 nm Laser Using Strontium Tetraborate For Frequency Conversion”, which was filed on Nov. 21, 2022; to U.S. Pat. No. 11,237,455 to Chuang et al.; to U.S. Pat. No. 11,567,391 to Chuang et al.; to U.S. Pat. No. 6,201,601 to Vacz-Iravani et al.; to U.S. Pat. No. 6,271,916 to Marxer et al.; to U.S. Pat. No. 7,525,649 to Leong et al.; to U.S. Pat. No. 7,817,260 to Chuang et al.; to U.S. Pat. Nos. 8,298,335 and 8,824,514 to Armstrong; to U.S. Pat. No. 8,976,343 to Genis; to U.S. Pat. No. 9,023,152 to Dribinski; to U.S. Pat. Nos. 9,461,435 and 9,059,560 to Dribinski et al.; to U.S. Pat. Nos. 9,293,882 and 9,660,409 to Chuang; to U.S. Pat. Nos. 9,250,178, 9,459,215, 9,509,112, 10,044,166 and 10,283,366 to Chuang et al.; and to U.S. Patent Application Publication No. 2014/0305367 to Dribinski et al.

It is noted that SBO exhibits unique optical and mechanical properties. The transparency range of SBO is 130-3200 nm in wavelength. See Y. S. Oseledchik, A. L. Prosvirnin, A. I. Pisarevskiy, V. V. Starshenko, V. V. Osadchuk, S. P. Belokrys, N. V. Svitanko, A. S. Korol, S. A. Krikunov, and A. F. Selevich, “New nonlinear optical crystals: strontium and lead tetraborates,” Opt. Mater. 4, 669 (1995), which is incorporated by reference herein in the entirety. This broad transparency range covers VUV, DUV, visible, and near infrared (IR) wavelength ranges. The VUV and DUV ranges are of particular interest to semiconductor inspection and metrology. It is also noted that the transmittance is high. For instance, the transmittance exceeds 80% from about 250 nm to about 2500 nm. This high transmittance makes SBO a good candidate for frequency generation especially for the UV wavelength range. If SBO is grown in optimal conditions, a better transmission curve can be obtained: the transmittance can reach more than 80% for wavelengths longer than 200 nm and more than 50% for 130 to 200 nm. Dielectric and optical properties of strontium tetraborate glasses are described by M. V. Shankar and K. B. R. Barma in “Dielectric and Optical Properties of Strontium Tetraborate Glass,” Journal of Materials Science Letters 15 (1996) 858-860, which is incorporated herein by reference in the entirety.

One material of recently increased interest for DUV frequency generation is SBO. SBO has a Pmn2₁ space group and mm2 point group, indicating that a d₃₃ nonlinear coefficient is possible for quasi-phase matching. This d₃₃ nonlinear coefficient has been measured as 1.5 pm/V for frequency doubling from 800 nm to 400 nm (Petrov, V., et al., “Application of the nonlinear crystal SrB₄O₇ for ultrafast diagnostics converting to wavelengths as short as 125 nm”, Optics Letters, 29, 4 (2004)). Further, SBO has DUV transparency for wavelengths as short as 125 nm, and frequency conversion to this wavelength has been shown. SBO has a UV light-induced damage threshold at 266 nm of 16.4 J/cm\hat{ }2, significantly higher than that of CaF₂ (11.4 J/cm\hat{ }2) and silica (4.8 J/cm\hat{ }2) (Tanaka et al., “High surface laser-induced damage threshold of SBO single crystals under 266-nm (DUV) laser irradiation” Optics Express, 28, 20 29239 (2020)). While biaxial, SBO is nearly isotropic (Oseledchik, Y. S. et al., “New nonlinear optical crystals: strontium and lead tetraborates”, Optical Materials 4, 669-674 (1995)), and so birefringent phase matching is not possible for frequency conversion in the DUV. Because of the high d₃₃ nonlinear coefficient, SBO is a candidate for quasi-phase matching, in which the fundamental and second harmonic are polarized parallel to each other and parallel to the c-axis. The phase mismatch caused by the different index of the fundamental and higher harmonic is compensated by alternatively flipping the direction of the c crystal axis of the material by 180 degrees, so that the phase difference between the harmonics is alleviated by the different sign of the nonlinear coefficient. See U.S. Patent Application No. 63/521,880, entitled “Growth of Quasi-Phase Matched Strontium Tetraborate and Lithium Triborate Crystals for Frequency Conversion,” incorporated herein by reference in its entirety.

Because the birefringence of SBO is small, it is a good candidate material for various linear optical components, such as windows, lenses, coating layers, bulbs, among other components. See U.S. Patent No. U.S. Pat. No. 11,255,797 B2, entitled “Strontium tetraborate as optical glass material,” incorporated herein by reference in its entirety.

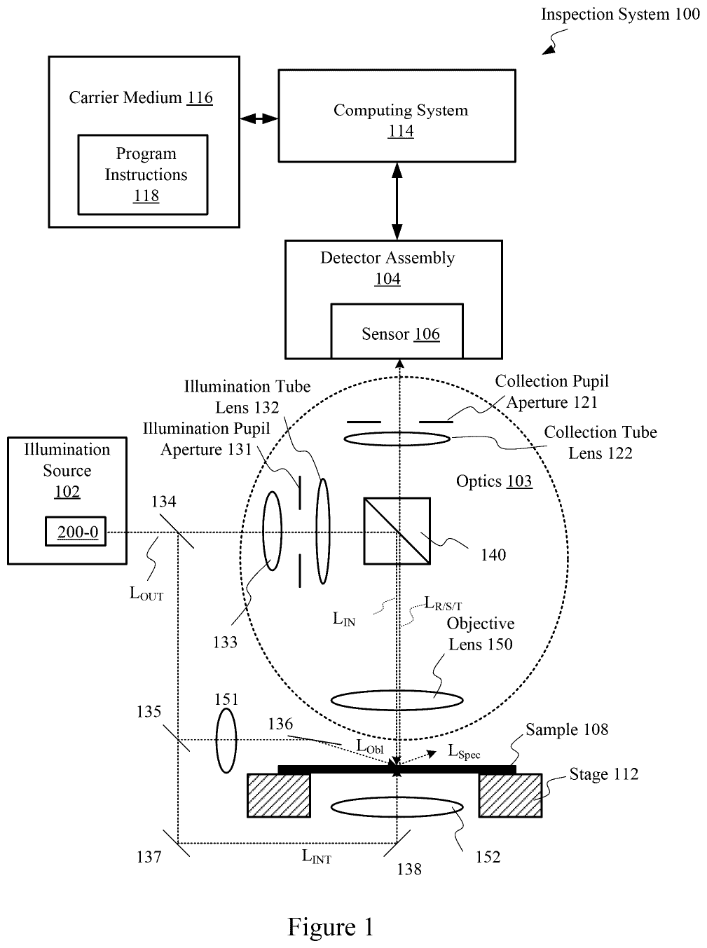

FIG. 1 shows an exemplary inspection system 100 configured to inspect or make measurements on a sample 108, in accordance with one or more embodiments of the present disclosure. Inspection system 100 may be configured as an inspection system or a metrology system that inspects and/or makes measurements on sample 108. Inspection system 100 may also be configured to cut, drill or ablate material from sample 108, or to expose a pattern onto photoresist on sample 108.

Sample 108 may include any sample known in the art such as, but not limited to, a wafer, reticle, photomask, or the like. In one embodiment, the sample 108 may be disposed on a stage assembly 112 to facilitate movement of the sample 108. The stage assembly 112 may include any stage assembly known in the art including, but not limited to, an X-Y stage, an R-θ stage, and the like. In another embodiment, the stage assembly 112 is capable of adjusting the height of the sample 108 during inspection to maintain focus on the sample 108. In yet another embodiment, a lens such as objective lens 150 may be moved up and down during inspection to maintain focus on the sample 108.

Inspection system 100 includes an illumination source 102 that incorporates a laser 200-0 that generates output light L_{OUT} having an output frequency ω_{OUT} with a corresponding a wavelength in a range between approximately 120 nm and approximately 200 nm. Illumination source 102 may include additional light sources such as a laser operating at a longer or shorter wavelength or a broadband light source. Laser 200-0 may incorporate grown SBO. Inspection system 100 includes one or more optical components such as beam splitters, mirrors, lenses, apertures and waveplates that are configured to condition and direct light L_{OUT} to sample 108, and can be configured from grown SBO. The optical components may be configured to illuminate an area, a line, or a spot on sample 108. In one embodiment beam splitter or mirror 134, mirrors 137 and 138 and lens 152 are configured to illuminate sample 108 from below so as to enable inspection or measurement of sample 108 by transmitting light L_{INT} through the sample. In another embodiment, beam splitters or mirrors 134 and 135, mirror 136 and lens 151 are configured to illuminate sample 108 with light at an oblique angle of incidence L_{Obl}, for example at an angle of incidence greater than 60° relative to a normal to the sample surface. In this embodiment, the specularly reflected light L_{Spec} may be blocked or discarded rather than collected. In yet another embodiment, optics 103 are collectively configured to direct illumination light L_{IN} to the top surface of sample 108.

When sample 108 is illuminated in one or more of the above-described modes, optics 103 is also configured to collect light L_{R/S/T} reflected, scattered, diffracted, transmitted and/or emitted from the sample 108 and direct and focus the light L_{R/S/T} to sensor 106 of a detector assembly 104. It is noted herein that sensor 106 and the detector assembly 104 may include any sensor 106 known in the art. The sensor may include, but is not limited to, a charge-coupled device (CCD) detector, a complementary metal oxide semiconductor (CMOS) detector, a time-delay integration (TDI) detector, a photomultiplier tube (PMT), an avalanche photodiode (APD), a line sensor, an electron-bombarded line sensor, or the like. Detector assembly 104 is communicatively coupled to a computing system 114.

Computing system 114 is configured to store and/or analyze data from detector assembly 104 under control of program instructions 118 stored on carrier medium 116. Computing system 114 may be further configured to control other elements of inspection system 100 such as stage 112, illumination source 102 and optics 103.

In one embodiment, the optics 103 includes an illumination tube lens 132. The illumination tube lens 132 may be configured to image an illumination pupil aperture 131 to a pupil within an objective lens 150. For example, the illumination tube lens 132 may be configured such that the illumination pupil aperture 131 and the pupil within the objective lens 150 are conjugate to one another. In one embodiment, the illumination pupil aperture 131 may be configurable by switching different apertures into the location of illumination pupil aperture 131. In another embodiment, the illumination pupil aperture 131 may be configurable by adjusting a diameter or shape of the opening of the illumination pupil aperture 131. In this regard, the sample 108 may be illuminated by different ranges of angles depending on the characterization (e.g., measurement or inspection) being performed under control of the controller 114. Illumination pupil aperture 131 may also include a polarizing element to control the polarization state of the illumination light L_{IN}.

In one embodiment, the one or more optical elements 103 include a collection tube lens 122. For example, the collection tube lens 122 may be configured to image the pupil within the objective lens 150 to a collection pupil aperture 121. For instance, the collection tube lens 122 may be configured such that the collection pupil aperture 121 and the pupil within the objective lens 150 are conjugate to one another. In one embodiment, the collection pupil aperture 121 may be configurable by switching different apertures into the location of collection pupil aperture 121. In another embodiment, the collection pupil aperture 121 may be configurable by adjusting a diameter or shape of the opening of collection pupil aperture 121. In this regard, different ranges of angles of illumination reflected or scattered from the sample 108 may be directed to detector assembly 104 under control of the controller 114. Collection pupil aperture 121 may also include a polarizing element so that a specific polarization of light L_{R/S/T} can be selected for transmission to sensor 106.

In another embodiment, the illumination pupil aperture 131 and/or the collection pupil aperture 121 may include a programmable aperture. Programmable apertures are generally discussed in U.S. Pat. No. 9,255,887, entitled “2D programmable aperture mechanism,” to Brunner, issued on Feb. 9, 2016; and U.S. Pat. No. 9,645,287, entitled “Flexible optical aperture mechanisms,” to Brunner, issued on May 9, 2017, both of which are herein incorporated by reference in the entirety. Methods of selecting an aperture configuration for inspection are generally described in U.S. Pat. No. 9,709,510, entitled “Determining a configuration for an optical element positioned in a collection aperture during wafer inspection,” to Kolchin et al., issued on Jul. 18, 2017; and U.S. Pat. No. 9,726,617, entitled “Apparatus and methods for finding a best aperture and mode to enhance defect detection,” to Kolchin et al, issued on Aug. 8, 2017, both of which are herein incorporated by reference in the entirety.

The various optical elements and operating modes depicted in FIG. 1 are merely to illustrate how laser 200-0 may be used in inspection system 100 and are not intended to limit the scope of the present disclosure. A practical inspection system 100 may implement a subset or a superset of the modes and optics depicted in FIG. 1. Additional optical elements and subsystems may be incorporated as needed for a specific application. The related references cited above, and the other references cited herein disclose many other important details of systems that may incorporate the inventive laser 200-0.

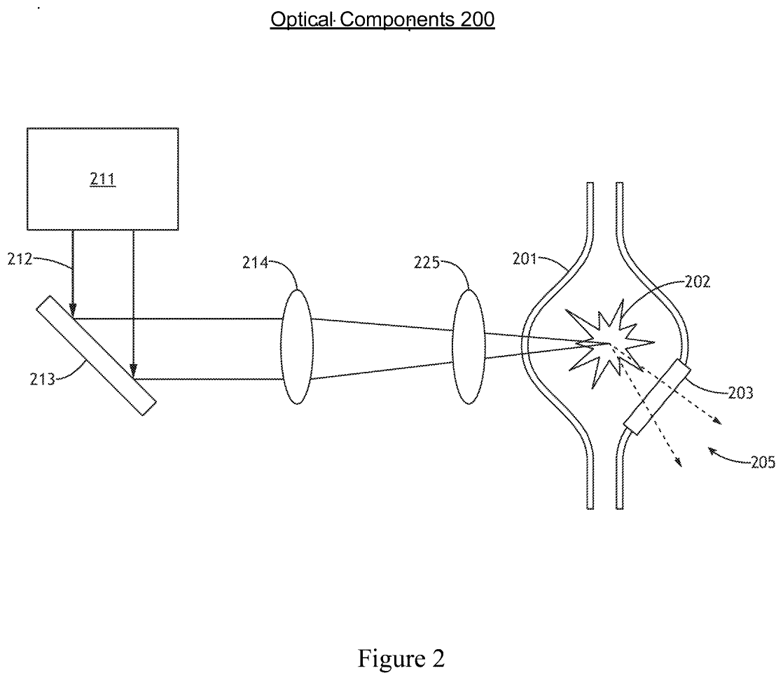

FIG. 2 illustrates a simplified schematic view of an ultraviolet lamp that incorporates SBO as an optical glass material for one or more optical components, in accordance with one or more embodiments of the present disclosure. The ultraviolet lamp may be a laser-driven light source. In this example, a laser 211 emits laser beam 212, which is directed by mirror 213 and focused by lens 214 and lens 225 and generates a plasma 202 inside a lamp cell 201. The plasma 202 emits broadband ultraviolet light 205 over a broad range of wavelengths including DUV wavelengths and/or VUV wavelengths. One or more windows 203 may be placed in a wall of the lamp cell 201 to enable broadband ultraviolet light 205 to be transmitted out of lamp cell 201. In one embodiment, the lamp cell 201 may be made of SBO. In this embodiment, SBO may be used to form a transparent bulb, which contains the gas for generating plasma 202. In another embodiment, the one or more windows 203 may be formed from SBO. In yet another embodiment, both the lamp cell 201 and the one or more windows 203 may be made of SBO. The overall light throughput of ultraviolet lamp may be improved by appropriately using SBO as the optical glass material for one or more optical components. The lifetime of ultraviolet lamp and key optical components may also be improved by using SBO. Any of the aforementioned optical components may be fabricated with SBO crystal or glass and the scope of the present disclosure is not at all limited to the SBO-based windows or plasma cells. Rather, as discussed previously herein, any number of linear optical components of the present disclosure may be formed from SBO and may be implemented in any optical context, which may include, but is not limited to, semiconductor inspection or metrology.

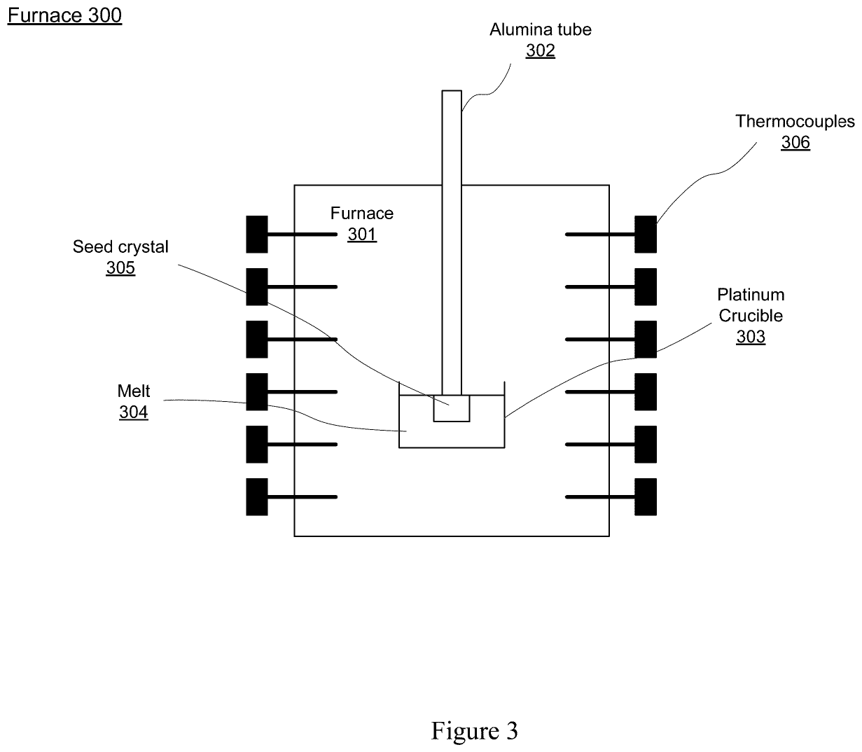

FIG. 3 illustrates a simplified furnace 301 for growing SBO from a seed 305 using the top seeded Kyropoulos method. Furnace 301 may comprise of a five-, six-, or more zone resistance heating furnace, comprising of a platinum crucible 303 with a diameter of about 150 mm and a height of about 150 mm. The platinum crucible 303 can be larger or smaller depending on the final size of the crystal grown, and should be about twice the diameter of the desired final crystal size. Seed crystal 305 is fixed to alumina tube 302 to prevent the seed crystal 305 from falling into the melt 304, and also to provide cooling liquid or air to the seed crystal 305 to prevent melting during growth.

The melt 304 comprises strontium carbonate (SrCO₃), boron trioxide (B₂O₃), and strontium chloride (SrCl₂). L-shaped or twin-type stirring blades may be used to promote melt mixing. The melt 304 temperature should remain near 1000° C. B₂O₃ has a high viscosity of approximately 9.8 Pa·s near 1000° C. (see Napolitano, A., et al in “Viscosity and Density of Boron Trioxide,” J. Am. Ceram. 48, 12 (1965)), causing a self-flux of B₂O₃ in Tanaka, Y., et al. to create an overall solution viscosity of about 1 Pa·s, which is detrimental to mixing and therefore crystal growth. Strontium chloride is a salt with a melting point of 874° C. and boiling point of 1250° C. The melting point of SBO is around 1015° C. and the recrystallization temperature is around 950° C., therefore, SrCl₂ is an ideal flux for top-seeded solution growth of SBO as SrCl₂ recrystallizes at a lower temperature than SBO. Additionally, SrCl₂ has a water soluble value of 53.8 g/100 mL at 20° C., and therefore excess SrCl₂ is easily removed from the SBO crystal after growth is complete via rinsing with water. The viscosity of SrCl₂ was measured as 2.25-3.75 mPa·s between 880-1050° C. (Tørklep, K. and Harald A. Øye in “Viscosity of Molten Alkaline-Earth Chlorides”, J. Chem. Eng. Data 27, 387 (1982)), which is three orders of magnitude lower than the viscosity of B₂O₃. This lower viscosity improves single crystal growth by replenishing depleted melt close to the surface of the growing crystal and improving temperature uniformity, which suppresses growth of other crystal phases. Cl-ions have a different number of valence shell electrons and has a larger ionic radius than the other atoms composing SBO, reducing Cl substitutional and interstitial defects. As the number of valence electrons of Sr²⁺ from the ionic liquid of melted SrCl₂ is the same as the number of valence electrons in Sr²⁺ from dissolved SrCO₃, the Sr²⁺ from SrCl₂ may participate significantly in crystal growth.

An exemplary chemical reaction to form SBO involving the raw materials B₂O₃ and SrCO₃ is

2B₂O₃+SrCO₃->SrB₄O₇+CO₂.

Other chemical reactions may occur involving the same or different stoichiometries of reactants. Other reactants may be involved, such as SrCl₂. The Sr²⁺ ions from molten SrCl₂ in the solution will be indistinguishable from the Sr²⁺ ions from dissolved SrCO₃. Other phases in the SrO—B₂O₃ system which crystalize at compositions and temperatures close to the formation of SrB₄O₇ have Sr:B ratios of greater than 1:4 (Kudrjavtcev, D. P. et al. in “Growth of a new strontium borate crystal Sr₄B₁₄O₂₅”, J. Crystal Growth 254 (2003)), which contributes to their preferential formation over SrB₄O₇ with stoichiometric Sr:B raw materials. B-rich starting stoichiometries are more desirable to avoid formation of other Sr—B—O phases, as has been observed in both top-seeded solution growth methods and hydrothermal methods. However, a higher B₂O₃ percentage will increase the viscosity of the melt.

Another exemplary chemical reaction to form SBO involving the raw materials H₃BO₃ and SrCO₃ is

4H₃BO₃+SrCO₃->SrB₄O₇+CO₂+6H₂O.

Other chemical reactions may occur involving the same or different stoichiometries of reactants. Other reactants may be involved. In this reaction, a SrCl₂ flux is added such that the Sr:B ratio in the solution is equal to or greater than 1:4.

Seed crystal 305 may comprise a single-crystal at a fixed orientation, or a patterned crystals such as that found in U.S. Provisional Patent Application KLA No. 63/521,880, entitled “Growth of Quasi-Phase Matched Strontium Tetraborate and Lithium Triborate Crystals for Frequency Conversion,” incorporated herein by reference in its entirety.

Optical glasses composed of SBO may be formed by melting single-crystal SBO grown with SrCl₂ incorporated in the melt. See U.S. Pat. No. 11,255,797, entitled “Strontium tetraborate as optical glass material”, issued to Chuang et al., for more details on fabricating SBO glasses. This patent is incorporated by reference herein. SBO optical coatings, used for example in anti-reflection coatings, can be deposited from these grown SBO single crystals via sputtering, electron-beam evaporation, thermal evaporation, pulsed-laser deposition, molecular beam epitaxy, or other thin-film deposition methods known to those skilled in the arts. These high damage threshold, DUV and VUV-transmission optical glasses and coatings can be used in semiconductor inspection and metrology systems, including in mirrors, lenses, laser crystals, windows, and lamps among other parts.

Although the present crystal growth method is described herein using various temperatures, pressures, melt stoichiometries, furnace types, crucible sizes, crucible and crystal rotation rates, unless otherwise specified in the appended claims, other temperatures, pressures, melt stoichiometries, furnace types, crucible sizes, and crucible and crystal rotation rates are considered within the scope of this invention.

Nonlinear crystals with transmission as low as approximately 120 nm are not commercially available. In particular, there is no prior art for mass-manufacturing SBO crystals larger than 350 g with high purity, high damage threshold, high nonlinear coefficient, and high transparency in the sub-200 nm region. The embodiments of the present method provide a lower viscosity melt for SBO growth enabling larger, higher purity boule formation. The present growth method additionally uses non-toxic melt composition, and therefore is easy and inexpensive to perform and maintain equipment for.

One skilled in the appropriate arts will readily appreciate that there are many possible applications of the inventive laser crystal growth methods described herein in addition to their use in semiconductor inspection and metrology. For example, a laser incorporation an SBO crystal grown with the present method operating at a wavelength close to 193.4 nm can be used in a lithography system configured to expose patterns into photoresist coated on a substrate such as a semiconductor wafer. In another example, a laser incorporation an SBO crystal grown with the present method operating at a wavelength between about 120 nm and 200 nm may be used in a system configured to cut or ablate biological tissue. Although the present disclosure has been described with respect to certain specific embodiments, it will be clear to those skilled in the art that the inventive features of the present disclosure are applicable to other embodiments as well, all of which are intended to fall within the scope of the present disclosure.

1. A method for growing a strontium tetraborate (SrB₄O₇) crystal comprising:
lowering a seed crystal into a melt, wherein the melt comprises:
forming a mixture comprising a source of Sr, B, O, and Cl; and
heating and melting the mixture to a temperature sufficient to form a strontium tetraborate crystal.

2. The method for growing a SrB₄O₇ crystal according to claim 1, wherein the mixture of Sr, B, O, and Cl is heated and melted to a temperature of approximately 960-1030° C., and then cooled to a temperature of approximately 950° C. to form the strontium tetraborate crystal.

3. The method for growing a SrB₄O₇ crystal according to claim 1, wherein a source of the Cl is SrCl₂.

4. The method for growing a SrB₄O₇ crystal according to claim 1, wherein a source of Sr, B, O, and Cl comprises at least one of B₂O₃, SrCO₃, and SrCl₂.

5. The method for growing a SrB₄O₇ crystal according to claim 3, wherein the melt comprises approximately between 0.5-34 mol % SrCl₂.

6. The method for growing a SrB₄O₇ crystal according to claim 4, wherein the melt comprises approximately between 0.5-34 mol % SrCO₃.

7. The method for growing a SrB₄O₇ crystal according to claim 4, wherein the melt comprises approximately between 66-90 mol % B₂O₃.

8. The method for growing a SrB₄O₇ crystal according to claim 3, wherein the melt comprises approximately between 2-15 mol % SrCl₂.

9. The method for growing a SrB₄O₇ crystal according to claim 1, wherein the mixture additionally comprises a source of H₂O.

10. The method for growing a SrB₄O₇ crystal according to claim 1, further comprising growing the strontium tetraborate crystal by a top-seeded solution method.

11. The method for growing a SrB₄O₇ crystal according to claim 1, further comprising growing the strontium tetraborate crystal by a flux method.

12. The method for growing a SrB₄O₇ crystal according to claim 1, further comprising growing the strontium tetraborate crystal by a melt method.

13. The method for growing a SrB₄O₇ crystal according to claim 1, which comprises a seed crystal of alternating crystal plates to enable quasi-phase matching.

14. (canceled)

15. (canceled)

16. The method for growing a SrB₄O₇ crystal according to claim 1, wherein the mixture of Sr, B, O, and Cl is heated and melted to a temperature of approximately 960-1030° C., and then cooled to a temperature of approximately 900° C. to form the strontium tetraborate crystal.

17. The method for growing a SrB₄O₇ crystal according to claim 1, wherein the mixture of Sr, B, O, and Cl is heated and melted to a temperature of approximately 960-1030° C., and then cooled to a temperature of approximately 875° C. to form the strontium tetraborate crystal.

18. The method for growing a SrB₄O₇ crystal according to claim 1, wherein the mixture of Sr, B, O, and Cl is heated and melted to a temperature of approximately 1001-1030° C., and then cooled to a temperature of approximately 1000° C. to form the strontium tetraborate crystal.

19. The method for growing a SrB₄O₇ crystal according to claim 1, wherein the mixture of Sr, B, O, and Cl is heated and melted to a temperature of approximately 1016-1030° C., and then cooled to a temperature of approximately 1015° C. to form the strontium tetraborate crystal.

20. The method for growing a SrB₄O₇ crystal according to claim 1, wherein the mixture of Sr, B, O, and Cl is heated and melted to a temperature of approximately 960-1030° C., and then cooled to a temperature of approximately between 875-1015° C. to form the strontium tetraborate crystal.

21. A frequency converting apparatus which contains a crystal grown in the method of claim 1.

22. A linear optical apparatus which contains a crystal grown in the method of claim 1.
